(19) United States
(12) Patent Application Publication
(10) Pub. No.: US 2025/0273536 A1
(43) Pub. Date: Aug. 28, 2025

(54) Integrated Active Cooling in Power Packages

(71) Applicant: Wolfspeed, Inc., Durham, NC (US)

(72) Inventor: Afshin Dadvand, Durham, NC (US)

(21) Appl. No.: 18/584,179

(22) Filed: Feb. 22, 2024

(51) Int. Cl. H01L 23/38; H01L 23/373; H10N 10/17; H10N 10/82; H10N 10/852; H10N 10/853; H10N 10/856

(52) U.S. Cl. CPC H01L 23/38; H01L 23/3735; H10N 10/17; H10N 10/82; H10N 10/852; H10N 10/853; H10N 10/856

(57) ABSTRACT

Semiconductor device packages are provided. In one example, the semiconductor device package includes a housing, a submount, a thermoelectric structure on the submount, at least one semiconductor die on the thermoelectric structure, and at least one connection structure extending from the housing that is coupled to the thermoelectric structure. The thermoelectric structure includes an array of thermoelectric semiconductor structures and is operable to adjust a temperature difference between a first side and a second side of the thermoelectric structure based on a bias voltage applied to the thermoelectric structure.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or can be learned from the description, or can be learned through practice of the embodiments.

One example aspect of the present disclosure is directed to a semiconductor device package. The semiconductor device package includes a submount, a thermoelectric structure on the submount, and one or more semiconductor die on the thermoelectric structure. The thermoelectric structure is operable to adjust a temperature difference between a first side of the thermoelectric structure and a second side of the thermoelectric structure based on a bias voltage applied to the thermoelectric structure.

Another example aspect of the present disclosure is directed to a semiconductor device package. The semiconductor device package includes a thermoelectric structure having an array of thermoelectric semiconductor structures. The semiconductor device package includes a semiconductor die on the thermoelectric structure.

Another example aspect of the present disclosure is directed to a semiconductor device package. The semiconductor device package includes a housing, a submount, a thermoelectric structure, at least one connection structure extending from the housing, and at least one semiconductor die on the thermoelectric structure. The at least one connection structure is coupled to the thermoelectric structure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a cross-sectional view of an example semiconductor device package according to example embodiments of the present disclosure;

FIG. 2 depicts an exploded view of an example semiconductor device package having an example thermoelectric structure according to example embodiments of the present disclosure;

FIG. 3 depicts a top view of the example semiconductor device package of FIG. 2 according to example embodiments of the present disclosure;

FIG. 4 depicts a top view of the example semiconductor device package of FIG. 2 according to example embodiments of the present disclosure;

FIGS. 5A-5B depict perspective views of an example semiconductor device package having an example thermoelectric structure according to example embodiments of the present disclosure;

FIGS. 6A-6B depict perspective views of an example semiconductor device package having an example thermoelectric structure according to example embodiments of the present disclosure;

FIGS. 7A-7B depict perspective views of an example semiconductor device package having an example thermoelectric structure according to example embodiments of the present disclosure;

FIGS. 8A-8B depict perspective views of an example semiconductor device package having an example thermoelectric structure according to example embodiments of the present disclosure;

FIGS. 9A-9B depict perspective views of an example semiconductor device package having an example thermoelectric structure according to example embodiments of the present disclosure;

FIG. 10 depicts an example semiconductor package of a semiconductor device according to example embodiments of the present disclosure; and

FIG. 11 depicts an example semiconductor package of a semiconductor device according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages (e.g., discrete semiconductor device packages and power modules) have been developed that include a semiconductor die, such as a metal-oxide-semiconductor field-effect transistor (MOSFET), a Schottky diode, and/or a high electron mobility transistor (HEMT) device. Semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Semiconductor device packages with Schottky diodes and/or HEMT devices may be employed in many of the same high-performance power applications described above for MOSFETs, sometimes in systems that also include discrete power packages of MOSFETs.

Example aspects of the present disclosure are directed to semiconductor device packages for use in semiconductor applications and other electronic applications. It should be understood that the terms “semiconductor device package” and “semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide and/or a Group-III nitride (e.g., gallium nitride).

In some examples, the one or more semiconductor die may include one or more semiconductor devices, such as transistors, diodes, and/or thyristors. For instance, in some examples, the one or more semiconductor die may include a MOSFET, such as a silicon carbide-based MOSFET. Additionally and/or alternatively, in some examples, the one or more semiconductor die may include a Schottky diode, such as a silicon carbide-based Schottky diode. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices for purposes of illustration and discussion. Those having ordinary skill in the art, using the disclosures provided herein, will understand that the power semiconductor package of the present disclosure may include other power semiconductor devices without deviating from the scope of the present disclosure, such as diodes (e.g., Schottky diodes, PiN diodes, etc.), insulated gate bipolar transistors, HEMTs, or other devices.

In some semiconductor packages, the one or more semiconductor die may be attached to a submount (e.g., lead frame) by a die-attach material between the one or more semiconductor die and the submount. For instance, in some examples, a die-attach material may be deposited on the submount, and the semiconductor die (or other component) may be placed on the die-attach material, and the die-attach material may be subjected to bonding or a bonding process (e.g., sintering) to secure the semiconductor die (or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the semiconductor package may use wire bond(s) (e.g., aluminum wire bond(s)) for interconnection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The semiconductor package may further include a housing in which the one or more semiconductor die may be arranged. The semiconductor package may also include one or more electrical leads extending from the housing. More particularly, in some examples, the housing may be or may include an encapsulating portion (e.g., epoxy mold compound (EMC)) formed around at least a portion of the submount and the one or more semiconductor die.

The one or more semiconductor die may further include one or more metallization structures. A “metallization structure” is any layer, structure, or other portion of a semiconductor die that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more electrodes, contacts, interconnections, bonding pads, backside layers, metal layers, or metal coatings of the semiconductor device on the semiconductor die.

Semiconductor device packages, such as discrete semiconductor packages and power modules, often undergo a variety of tests during and after the manufacturing process to determine the quality, reliability, and functionality of the semiconductor package and its various components. One such reliability test, known by those having ordinary skill in the art as “thermal cycling” (TC), is commonly used to stress test the microstructural reliability and durability of microelectronic devices, such as the semiconductor devices and packages discloses herein. In particular, thermal cycling is a process of subjecting semiconductor devices/materials to repeated, quick cycles of alternating extreme temperature changes to simulate real-world operating conditions. In this manner, thermal cycling may be used to identify potential reliability issues of the semiconductor devices/materials, such as thermomechanical-induced failures.

However, thermal cycling tests (and other temperature-related tests) may adversely affect the semiconductor devices and packages due to the repeated material expansion and contraction caused by the extreme temperature changes, such as thermomechanical stress-induced failures, solder joint fatigue, degradation and delamination, metallization failures, and the like. Moreover, the temperature-induced anomalies and degradation may be compounded during actual use of the semiconductor device/package under real-world operating conditions, particularly during high-temperature operation (e.g., around and/or above an upper bound of its temperature rating). In addition to the adverse effects discussed above, testing and/or operating semiconductor devices/packages at high temperatures may adversely affect its performance, reliability, and lifespan due to, for instance, increased leakage currents, threshold voltage shifts, electromigration, carrier mobility reductions, accelerated aging, and the like. Hence, heat dissipation systems and structures play an important role in the overall performance, reliability, and lifespan of semiconductor devices and packages.

Accordingly, in addition to other system-level thermal dissipation paths and systems (e.g., topside cooling, heat sinks, etc.), example aspects of the present disclosure provide semiconductor devices and semiconductor device packages having thermoelectric structures integrated therein. As will be discussed in greater detail below, the thermoelectric structures described herein may enhance the overall heat dissipation efficiency of the corresponding semiconductor device and/or semiconductor device package. In this manner, semiconductor devices and semiconductor device packages according to the present disclosure may be tested and/or operated at increased temperatures or in high thermal stress conditions while, at the same time, reducing the adverse effects typically associated with such conditions.

More particularly, in some examples, the thermoelectric structure may be a thin thermoelectric film integrated inside the semiconductor device package. One or more semiconductor die may be on one side the thermoelectric structure, while the opposite side of the thermoelectric structure may be coupled to the submount (e.g., via a die-attach material). For instance, the thermoelectric structure may include a first layer that defines a first side of the thermoelectric structure, a second layer that defines a second side of the thermoelectric structure, and a plurality of thermoelectric semiconductor structures between the first layer and the second layer. In some examples, the plurality of thermoelectric semiconductor structures may be arranged in an array between the first layer and the second layer. In this manner, the thermoelectric structure may be operable to adjust a temperature difference between the first side of the thermoelectric structure and the second side of the thermoelectric structure based on a bias voltage that is applied thereto.

For instance, in some examples, the plurality of thermoelectric semiconductor structures may include a plurality of p-type thermoelectric semiconductor structures and a plurality of n-type thermoelectric semiconductor structures alternately arranged in an array. As used herein, a “p-type” thermoelectric semiconductor structure is a thermoelectric semiconductor structure that includes a “p-type” semiconductor material, and an “n-type” thermoelectric semiconductor structure is a thermoelectric semiconductor structure that includes an “n-type” semiconductor material. As noted below, a “p-type” semiconductor material includes a majority equilibrium concentration of positively charged holes, and an “n-type” semiconductor material includes a majority equilibrium concentration of negatively charged electrons.

In some examples, the thermoelectric structure may include a plurality of interconnects (e.g., traces) coupling adjacent thermoelectric semiconductor structures in the array. For instance, the plurality of p-type thermoelectric semiconductor structures may be alternately arranged in series with the plurality of n-type thermoelectric semiconductor structures via one or more first interconnects (e.g., contacting the first layer of the thermoelectric structure) and one or more second interconnects (e.g., contacting the second layer of the thermoelectric structure). The thermoelectric structure may further include a first connection structure (e.g., first bias voltage connection structure) coupled to one of the plurality of n-type thermoelectric semiconductor structures and a second connection structure (e.g., second bias voltage connection structure) coupled to one of the plurality of p-type thermoelectric semiconductor structures.

To enhance the heat dissipation efficiency of the example semiconductor devices and packages described herein, the Peltier effect of the thermoelectric semiconductor structures incorporated within the thermoelectric structure may be utilized. More particularly, the Peltier effect is a thermoelectric phenomenon where an electrical current passing through a junction of two dissimilar conductive materials causes a temperature difference across the junction. In other words, one side of the junction absorbs heat while the other side releases heat, thereby resulting in a temperature difference between the low temperature (endothermic) side and the high temperature (exothermic) side.

For instance, as will be discussed in greater detail below, a bias voltage may be applied to the thermoelectric structure via the first connection structure and/or the second connection structure. Due to the electrical properties of the thermoelectric semiconductor structures (e.g., p-type thermoelectric semiconductor structures and n-type thermoelectric semiconductor structures) in the array, the temperature at one side of the thermoelectric structure will increase, while the temperature at the other side of the thermoelectric structure will decrease. In this manner, heat applied to and generated by the semiconductor device and package may be transferred from the low temperature side to the high temperature side of the thermoelectric structure which, in turn, enhances the heat dissipation efficiency of the semiconductor device and package as a whole. Put differently, the thermoelectric structure may be operable to pull heat from the one or more semiconductor die on the thermoelectric structure, through the thermoelectric structure, to the submount.

Aspects of the present disclosure provide a number of technical effects and benefits. For instance, by including one or more thermoelectric structures between the one or more semiconductor die and the submount, example aspects of the present disclosure provide an additional cooling path to extract heat from semiconductor devices (e.g., on the one or more semiconductor die) during testing and/or operation. In this way, the heat dissipation efficiency of the semiconductor devices and packages may be enhanced. Moreover, by reducing and extracting this excess heat, thermomechanical stress on the semiconductor device package and its internal components may be reduced, thereby enhancing performance and reliability and also prolonging lifespan. Furthermore, by providing the thermoelectric structure as a thin thermoelectric film, a magnitude of the applied bias voltage necessary to produce the desired thermoelectric cooling effects discussed herein may be decreased. Thus, example aspects of the present disclosure provide robust semiconductor devices and semiconductor device packages with increased reliability, durability, and performance at or beyond normal operating and/or testing conditions.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

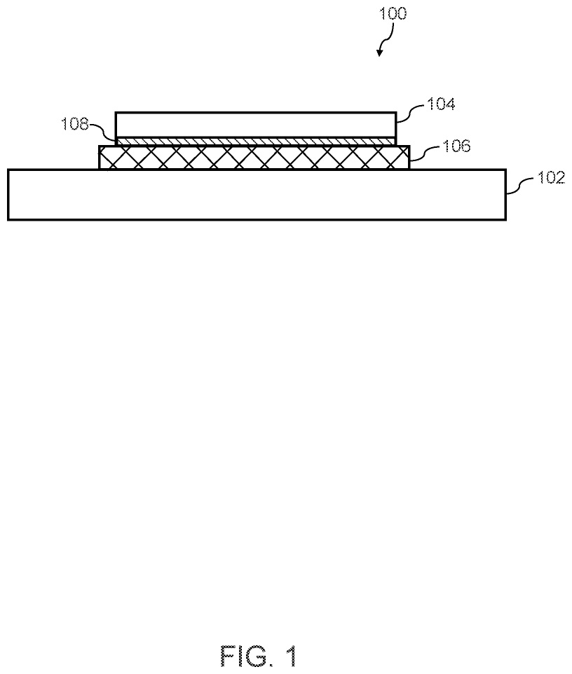

FIG. 1 depicts a cross-sectional view of an example semiconductor device package according to example embodiments of the present disclosure. More particularly, a cross-sectional view of at least a portion of a semiconductor device package 100 is depicted. In some examples, the portion of the semiconductor device package 100 depicted in FIG. 1 may be a portion of a discrete semiconductor package. Additionally and/or alternatively, in some examples, the portion of the semiconductor device package 100 depicted in FIG. 1 may be a portion of a power module. It should be understood that FIG. 1 is intended to represent structures for identification and description and is not intended to represent the structures to physical scale.

As shown, the semiconductor device package 100 may include a submount 102. The submount 102 may be, for instance, a copper submount 102 or may include other suitable conducting materials(s). For instance, in some examples, the submount 102 may include a direct bonded copper (DBC) substrate, an active metal brazed (AMB) substrate, and/or other power substrate.

The semiconductor device package 100 may include a semiconductor die 104. In some examples, the semiconductor die 104 may be fabricated from wide bandgap semiconductor materials (e.g., having a band gap greater than 1.40 eV). For high power, high temperature, and/or high frequency applications, devices formed in wide bandgap semiconductor materials such as silicon carbide (e.g., 2.996 eV band gap for alpha silicon carbide at room temperature) and/or the Group III-nitrides (e.g., 3.36 eV band gap for gallium nitride at room temperature) may provide higher electric field breakdown strengths and higher electron saturation velocities. As such, the semiconductor die 104 may include one or more semiconductor devices, such as one or more wide bandgap semiconductor devices.

For instance, in some examples, the semiconductor die 104 may include a silicon carbide-based metal-oxide-semiconductor field-effect transistor (MOSFET), a silicon carbide-based Schottky diode, and/or a Group-III nitride-based high electron mobility transistor (HEMT) device. It should be understood that the semiconductor die 104 may include any suitable semiconductor device, such as, by way of non-limiting example, field-effect transistor (FET) devices, double-diffused metal-oxide semiconductor (DMOS) transistors, metal-semiconductor field-effect transistors (MESFETs), laterally-diffused metal-oxide semiconductors (LDMOS) transistor devices, and the like.

To mitigate the excess heat-related adverse effects discussed herein and to ensure reliable operation across wide temperature ranges, the semiconductor device package 100 may include a thermoelectric structure 108 (e.g., thermoelectric film) between the submount 102 and the semiconductor die 104. As will be discussed in greater detail below, the semiconductor die 104 may be coupled to the thermoelectric structure 108, which may be attached to the submount 102 using a die-attach material 106. In some examples, the die-attach material 106 may include a sintered material, such as sintered silver and/or sintered copper. In some examples, the die-attach material 106 may include solder, paste, and the like. In this manner, the thermoelectric structure 108 may be on the submount 102. As such, the submount 102 may be, for instance, a lead frame or other supporting structure for a semiconductor device of the semiconductor device package 100.

It should be understood that the semiconductor device package 100 is depicted in FIG. 1 as including only one semiconductor die 104. Those having ordinary skill in the art, using the disclosures provided herein, will appreciate that the semiconductor device package 100 may include any number of semiconductor die 104 without deviating from the scope of the present disclosure.

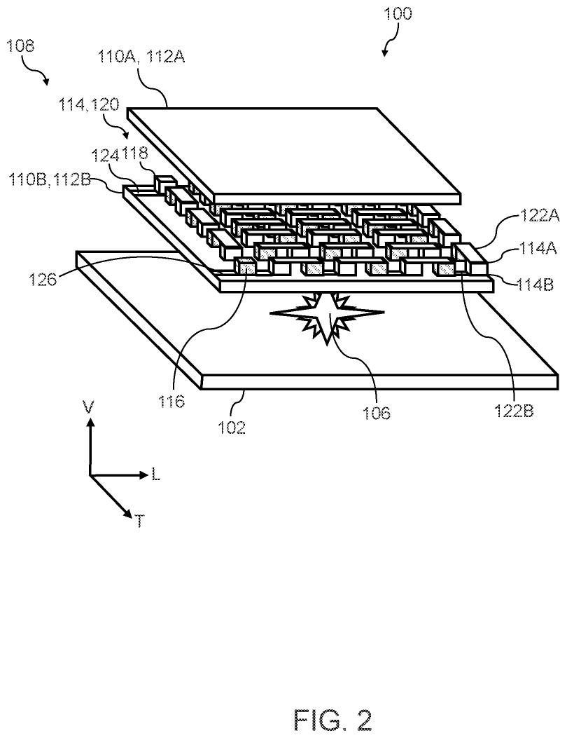

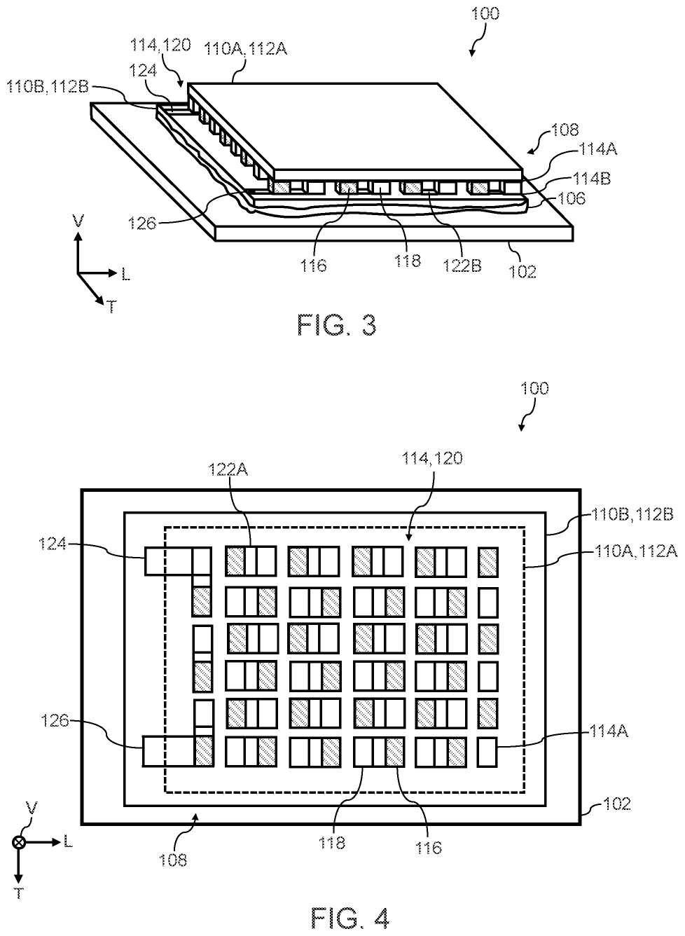

Referring now to FIGS. 2-4, a portion of the semiconductor device package 100 is depicted according to example embodiments of the present disclosure. More particularly, FIG. 2 depicts a three-dimensional exploded view of the portion of the semiconductor device package 100, FIG. 3 depicts a compressed perspective view of the portion of the semiconductor device package 100, and FIG. 4 depicts a top view of the portion of the semiconductor device package 100. It should be understood that FIGS. 2-4 are intended to represent structures for identification and description and is not intended to represent the structures to physical scale. As shown, the semiconductor device package 100 and its components generally define a vertical direction V, a lateral direction L, and a transverse direction T. Each direction V, L, T is perpendicular to one another, such that an orthogonal coordinate system is generally defined. Furthermore, it should be understood that, as used herein, “thickness” refers to a distance along the vertical direction V, “length” refers to a distance along the transverse direction T, and “width” refers to a distance along the lateral direction L.

As noted above, excess heat may adversely affect the semiconductor device package 100 and its various internal components, which may result in performance degradation, reliability issues, and device failure. For instance, during testing (e.g., thermal cycling (TC)) and/or operation, the semiconductor device package 100 may be subjected to temperatures that are near or above its rated operating temperature. In such instances, the reliability and performance of the semiconductor device package 100 may be degraded, and the semiconductor device package 100 and its internal components may experience accelerated aging resulting in a decreased lifespan.

To mitigate the excess heat-related adverse effects discussed herein and to ensure reliable operation across wide temperature ranges, the semiconductor device package 100 may include a thermoelectric structure 108, such as a thermoelectric film, on the submount 102. More particularly, the thermoelectric structure 108 may be coupled to the submount 102 using, for instance, the die-attach material 106. As will be discussed in greater detail below, the thermoelectric structure 108 may be operable to adjust a temperature difference between a first side 110A of the thermoelectric structure 108 and a second side 110B of the thermoelectric structure 108 based on a bias voltage applied to the thermoelectric structure 108.

As shown, the thermoelectric structure 108 may include a first layer 112A and a second layer 112B. The first layer 112A may define the first side 110A of the thermoelectric structure 108, and the second layer 112B may define the second side 110B of the thermoelectric structure 108. In some examples, the first layer 112A and the second layer 112B may include a ceramic material, such as, by way of non-limiting example, aluminum nitride (AlN), aluminum oxide (Al₂O₃), and the like. In some examples, the first layer 112A and the second layer 112B may include the same ceramic materials. In other examples, the first layer 112A and the second layer 112B may include different ceramic materials. Furthermore, the first layer 112A and the second layer 112B may be thin ceramic layers having a limited thickness along the vertical axis V. For instance, in some examples, each of the first layer 112A and the second layer 112B may have a thickness in a range of about 0.3 microns (μm) to about 5 microns (μm), such as about 0.5 microns (μm) to about 3.5 microns (μm), such as about 1 micron (μm) to about 2 microns (μm). It should be noted that, although depicted in FIGS. 2-4 as having an equal thickness to the second layer, the first layer 112A may have a different thickness than the second layer 112B without deviating from the scope of the present disclosure.

The thermoelectric structure 108 may further include a plurality of thermoelectric semiconductor structures 114 between the first layer 112A and the second layer 112B. Each thermoelectric semiconductor structure 114 may have a thickness along the vertical direction V, a length along the transverse axis T, and a width along the lateral axis L. For instance, in some examples, each thermoelectric structure 114 may have a thickness in a range of about 0.1 microns (μm) to about 20 microns (μm), such as about 0.5 microns (μm) to about 15 microns (μm), such as about 1 micron (μm) to about 10 microns (μm). In some examples, each thermoelectric structure 114 may have a length in a range of about 1 micron (μm) to about 1000 microns (μm), such as about 2 microns (μm) to about 500 microns (μm), such as about 3 microns (μm) to about 100 microns (μm). In some examples, each thermoelectric structure 114 may have a width in a range of about 1 micron (μm) to about 1000 microns (μm), such as about 2 microns (μm) to about 500 microns (μm), such as about 3 microns (μm) to about 100 microns (μm).

As shown, each thermoelectric semiconductor structure 114 may include a first side 114A and an opposing second side 114B. The first side 114A may contact the first layer 112A of the thermoelectric structure 108, and the second side 114B may contact the second layer 112B of the thermoelectric structure 108.

More particularly, the plurality of thermoelectric semiconductor structures 114 may include a plurality of p-type thermoelectric semiconductor structures 116 and a plurality of n-type thermoelectric semiconductor structures 118. As noted above, a p-type thermoelectric semiconductor structure 116 includes a “p-type” semiconductor material (e.g., doped semiconductor material having a majority equilibrium concentration of positively charged holes), and an n-type thermoelectric semiconductor structure 118 includes an “n-type” semiconductor material (e.g., doped semiconductor material having a majority equilibrium concentration of negatively charged electrons).

In some examples, the plurality of p-type thermoelectric semiconductor structures 116 and the plurality of n-type thermoelectric semiconductor structures 118 may include a bismuth (Bi) alloy, such as, for instance, bismuth telluride (Bi₂Te₃). As used herein, the term “alloy” refers to a mixture of metal elements. More particularly, in some examples the plurality of p-type thermoelectric semiconductor structures 116 may include bismuth telluride doped with antimony (Sb) (e.g., (Bi,Sb)₂Te₃), and the plurality of n-type thermoelectric semiconductor structures 118 may include bismuth telluride doped with selenium (Se) (e.g., Bi₂(Te,Se)₃).

Additionally and/or alternatively, in some examples, the plurality of p-type thermoelectric semiconductor structures 116 and the plurality of n-type thermoelectric semiconductor structures 118 may include a conductive polymer. More particularly, the conductive polymer may include, for instance, poly(3,4-ethylenedioxythiophene) polystyrene sulfonate (PEDOT:PSS), polyaniline (PANI), polythiophene (PTH), poly(p-phenylene vinylene) (PPV), and the like. For instance, by way of non-limiting example, each of the plurality of p-type thermoelectric semiconductor structures 116 may include a p-type PEDOT-carbon nanotube (CNT) composite, and each of the plurality of n-type thermoelectric semiconductor structures 118 may include an n-type polyethylenimine (PEI) doped PEDOT-carbon nanotube (CNT) composite.

In some examples, the plurality of thermoelectric semiconductor structures 114 (e.g., p-type thermoelectric semiconductor structures 116, n-type thermoelectric semiconductor structures 118) may be arranged in an array 120 between the first layer 112A and the second layer 112B. For instance, as shown in FIGS. 2-4, the plurality of p-type thermoelectric semiconductor structures 116 may be alternately arranged with the plurality of n-type thermoelectric semiconductor structures 118 in the array 120. Furthermore, each thermoelectric semiconductor structure 114 (e.g., each p-type thermoelectric semiconductor structure 116, each n-type thermoelectric semiconductor structure 118) may be separated from adjacent thermoelectric semiconductor structures 114 by a distance in a range of about 0.2 microns (μm) to about 100 microns (μm), such as about 0.5 microns (μm) to about 50 microns (μm), such as about 1 micron (μm) to about 10 microns (μm).

The thermoelectric structure 108 may further include a plurality of interconnects 122 (e.g., copper traces) coupling adjacent thermoelectric semiconductor structures 114 (e.g., p-type thermoelectric semiconductor structures 116, n-type thermoelectric semiconductor structures 118) in the array 120. More particularly, the plurality of interconnects 122 may include one or more first interconnects 122A and one or more second interconnects 122B. The one or more first interconnects 122A may contact the first layer 112A of the thermoelectric structure 108, and the one or more second interconnects 122B may contact the second layer 112B of the thermoelectric structure 108. Each of the first interconnects 122A may contact a respective first side 114A of one or more thermoelectric semiconductor structures 114 (e.g., p-type thermoelectric semiconductor structures 116, n-type thermoelectric semiconductor structures 118) in the array 120; each of the second interconnects 122B may contact a respective second side 114B of one or more thermoelectric semiconductor structures 114 (e.g., p-type thermoelectric semiconductor structures 116, n-type thermoelectric semiconductor structures 118) in the array 120. Furthermore, each interconnect 122 may have a limited thickness along the vertical direction V. For instance, in some examples, each interconnect 122 (e.g., each first interconnect 122A, each second interconnect 122B) may have a thickness in a range of about 0.2 microns (μm) to about 10 microns (μm), such as about 0.5 microns (μm) to about 8 microns (μm), such as about 1 micron (μm) to about 5 microns (μm).

The thermoelectric semiconductor structure 108 may further include a first connection structure 124 and a second connection structure 126. By way of non-limiting example, the first connection structure 124 and the second connection structure 126 may be one of a pin, a lead, a terminal, a contact, an interconnect, a bonding pad, and/or the like. The first connection structure 124 may be coupled to one of the plurality of n-type thermoelectric semiconductor structures 118, and the second connection structure 126 may be coupled to one of the plurality of p-type thermoelectric semiconductor structures 116. Each of the plurality of p-type thermoelectric semiconductor structures 116 and each of the plurality of n-type thermoelectric semiconductor structures 118 may be alternately arranged in series (e.g., coupled via interconnects 122) between the first connection structure 124 and the second connection structure 126. Thus, as shown, the first connection structure 124 may be coupled to a first end 120A of the array 120, and the second connection structure 126 may be coupled to a second end 120B of the array 120.

As noted above, the Peltier effect of the thermoelectric semiconductor structures 114 (e.g., the p-type thermoelectric semiconductor structures 116 and the n-type thermoelectric semiconductor structures 118) may allow the thermoelectric structure 108 to enhance the heat dissipation efficiency of the semiconductor device package 100. The thermoelectric structure 108 may be operable to adjust a temperature difference between the first side 110A (e.g., first layer 112A) of the thermoelectric structure 108 and the second side 110B (e.g., second layer 112B) of the thermoelectric structure 108 based on a bias voltage applied to the thermoelectric structure 108.

More particularly, when a bias voltage (e.g., direct-current (DC) bias voltage) is applied to a first bias voltage connection structure (e.g., first connection structure 124) and/or a second bias voltage connection structure (e.g., second connection structure 126), the alternating arrangement of the plurality of interconnects 122 (e.g., first interconnects 122A contacting first layer 112A, second interconnects 122B contacting second layer 112B) cause a temperature at one side (e.g., first side 110A or second side 110B) of the thermoelectric structure 108 to decrease (forming an endothermic (e.g., heat-absorbing) side), while also causing a temperature at the other side (e.g., first side 110A or second side 110B) of thermoelectric structure 108 will increase (forming an exothermic (e.g., heat-releasing) side). In this manner, heat may be transferred from one side of the thermoelectric structure 108—through the thermoelectric semiconductor structures 114 in the array 120—to the opposing side of the thermoelectric structure 108.

The thermoelectric structure 108 may adjust a direction of the temperature difference between the first side 110A and the second side 110B based on the bias voltage connection structure (e.g., first connection structure 124, second connection structure 126) on which the bias voltage is applied. By way of non-limiting example, when a bias voltage is applied to the first connection structure 124, heat may be transferred from the first side 110A to the second side 110B (e.g., through the thermoelectric structure 108); when a bias voltage is applied to the second connection structure 126, heat may be transferred from the second side 110B to the first side 110A (e.g., through the thermoelectric structure 108). Hence, based on the applied bias voltage, the thermoelectric structure 108 may pull heat from one or more or more semiconductor die (not shown) on, for instance, the first side 110A of the thermoelectric structure, through the thermoelectric structure 108, to the submount 102 coupled to the second side 110B of the thermoelectric structure 108.

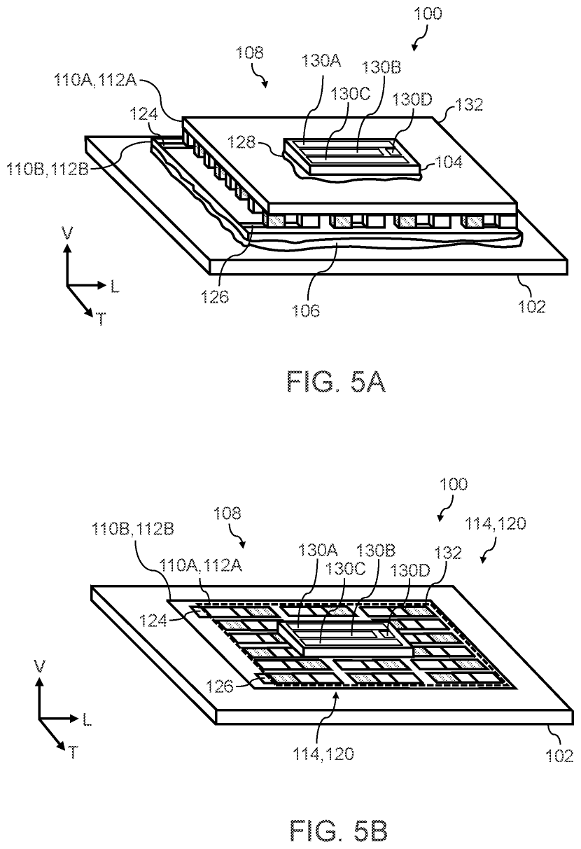

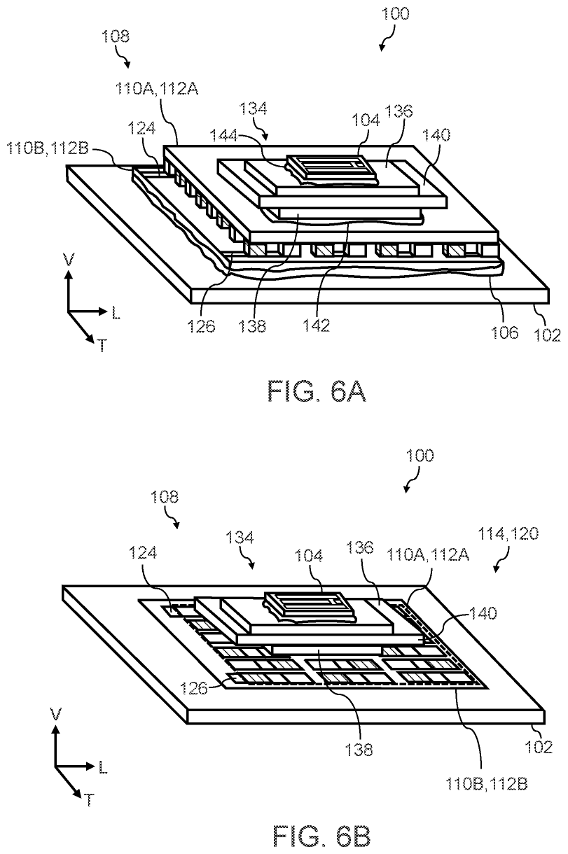

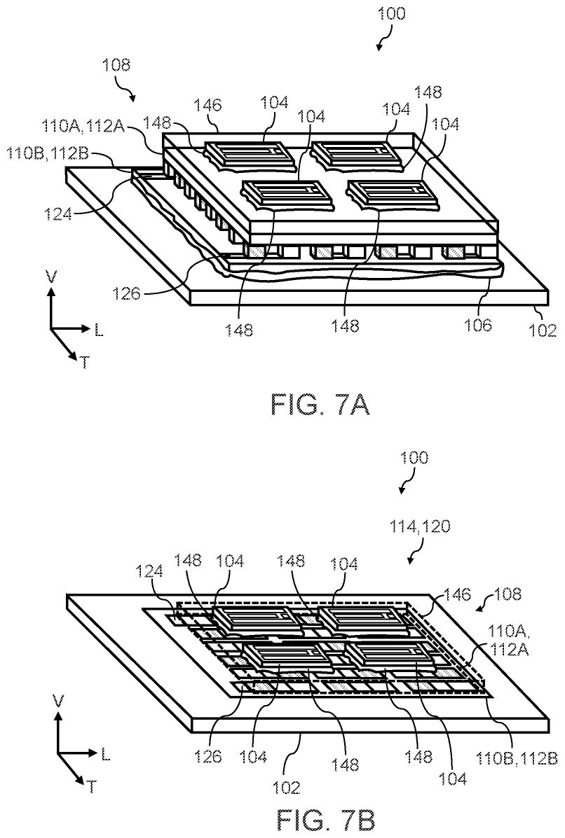

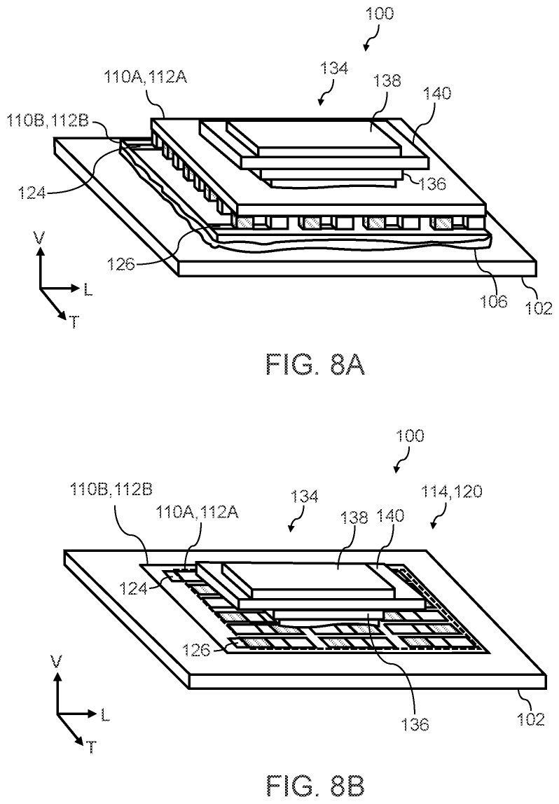

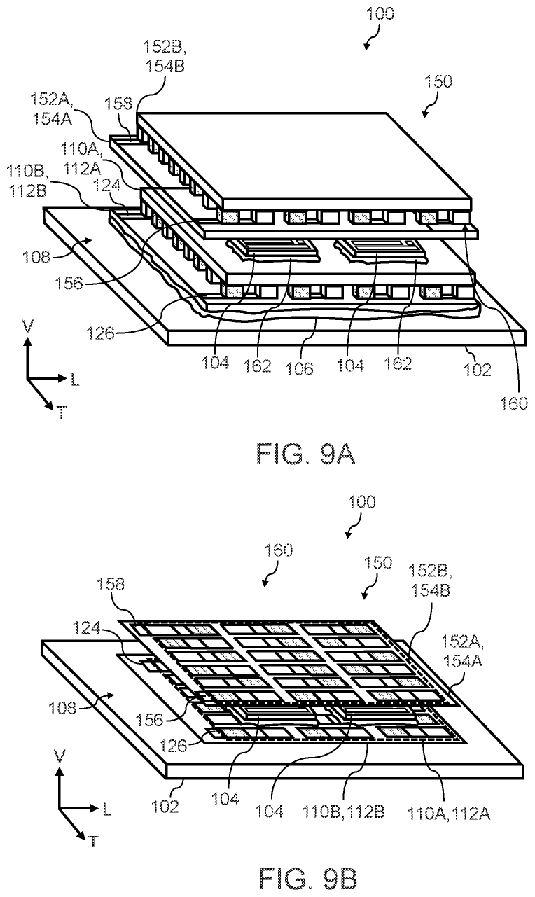

Variations and modifications may be made to the example semiconductor device package 100 and the example thermoelectric structure 108 described herein without deviating from the scope of the present disclosure. For instance, in some examples (FIGS. 5A-5B), the semiconductor device package 100 may further include a heat sink 132 coupled to the thermoelectric structure 108. Additionally and/or alternatively, in some examples (FIGS. 6A-6B), the semiconductor device package 100 may further include a power substrate 134 between the thermoelectric structure 108 and the one or more semiconductor die 104. Additionally and/or alternatively, in some examples (FIGS. 7A-7B), the semiconductor device package 100 may include multiple submounts 102, 146 and a plurality of semiconductor die 104. Additionally and/or alternatively, in some examples (FIGS. 8A-8B), the semiconductor device package 100 may include one or more semiconductor die 104 mounted thereon in a flip-chip configuration. Additionally and/or alternatively, in some examples (FIGS. 9A-9B), the semiconductor device package 100 may include multiple thermoelectric structures 108, 150.

It will be appreciated that the specific configurations, structures, arrangements, materials, and the like that are depicted in FIGS. 5A-9B and/or described below are merely provided as examples to illustrate in detail the structure of specific example embodiments. Thus, the specific details depicted in FIGS. 5A-9B and/or described below are not limiting to the present disclosure.

As an illustrative example, FIGS. 5A-5B depict perspective views of the example semiconductor device package 100 discussed above according to example embodiments of the present disclosure. More particularly, FIG. 5A depicts a perspective view of the example semiconductor device package 100. FIG. 5B depicts a compressed perspective view of the example semiconductor device package 100 depicted in FIG. 5A with a translucent first side 110A/first layer 112A to show the array 120 of thermoelectric semiconductor structures 114 of the thermoelectric structure 108. FIGS. 5A-5B are intended to represent structures for identification and description and is not intended to represent the structures to physical scale.

As shown, the semiconductor device package 100 may include a submount 102 and a thermoelectric structure 108 on the submount 102. The semiconductor device package 100 may further include one or more semiconductor die 104 on the thermoelectric structure 108. A die-attach material 128 may couple the one or more semiconductor die 104 to the first side 110A of the thermoelectric structure 108. It should be understood that the die-attach material 128 may be similar to the die-attach material 106 coupling the thermoelectric structure 108 to the submount 102. In some examples, the die-attach material 128 may include the same material as the die-attach material 106. In other examples, the die-attach material 128 may include a different material than the die-attach material 106. Those having ordinary skill in the art, using the disclosures provided herein, will understand that any suitable die-attach material 106, 128 may be used without deviating from the scope of the present disclosure.

As noted above, the one or more semiconductor die 104 may include one or more lateral semiconductor devices. More particularly, in some examples, the one or more semiconductor die 104 may include at least one connection structure 130 operable to provide electrical and/or thermal connections for the semiconductor device package 100. For instance, in some examples, the one or more semiconductor die 104 may include at least one source connection structure 130A operable to provide a source connection, at least one gate connection structure 130B operable to provide a gate connection, and at least one drain connection structure 130C operable to provide a drain connection. In some examples, the one or more semiconductor die 104 may further include an additional connection structure 130D operable to provide another connection, such as a kelvin connection, sensor connection, or other suitable connection. Furthermore, as noted above, the connection structures 130A-130D may be any suitable connection structure, such as a pin, a lead, a terminal, a contact, an interconnect, a bonding pad, and/or the like.

As noted above, the thermoelectric structure 108 may be operable to adjust a temperature difference between the first side 110A of the thermoelectric structure 108 and the second side 110B of the thermoelectric structure 108 based on a bias voltage applied to one of the bias voltage connection structures (e.g., first connection structure 124, second connection structure 126). In this manner, the thermoelectric structure 108 may be operable to pull heat from the one or more semiconductor die 104, through the array 120 of thermoelectric semiconductor structures 114, to the submount 102. Hence, in some examples, the first layer 112A of the thermoelectric structure 108 may be a heat sink 132. For instance, in some examples, the heat sink 132 may include a thermally conductive material, such as a metal and/or the like. Although not depicted in FIGS. 5A-5B, in some examples, a separate heat sink structure (e.g., thermally conductive heat sink) may be coupled between the one or more semiconductor die 104 and the first side 110A of the thermoelectric structure 108.

Although depicted in FIGS. 5A-5B as having one or more lateral semiconductor devices, in some examples, the semiconductor die 104 may include one or more vertical semiconductor devices. More particularly, in such examples, the die-attach material 128 may provide for an electrical connection between the semiconductor die 104 and the heat sink 132 such that the semiconductor die 104 is electrically coupled to the heat sink 132.

As another illustrative example, FIGS. 6A-6B depict perspective views of the example semiconductor device package 100 discussed above according to example embodiments of the present disclosure. More particularly, FIG. 6A depicts another perspective view of the example semiconductor device package 100. FIG. 6B depicts a compressed perspective view of the example semiconductor device package 100 depicted in FIG. 6A with a translucent first side 110A/first layer 112A to show the array 120 of thermoelectric semiconductor structures 114 of the thermoelectric structure 108. FIGS. 6A-6B are intended to represent structures for identification and description and is not intended to represent the structures to physical scale.

As noted above, in some examples, the semiconductor device package 100 may further include a power substrate 134, such as a direct bonded copper (DBC) substrate, an active metal brazed (AMB) substrate, and/or the like. More particularly, the semiconductor device package 100 may include the power substrate 134 between the thermoelectric structure 108 and the one or more semiconductor die 104. As shown, the power substrate 134 may include a first conducting layer 136, a second conducting layer 138, and an insulating layer 140 between the first conducting layer 136 and the second conducting layer 138. Furthermore, a die-attach material 142 may couple the power substrate 134 to the thermoelectric structure 108 (e.g., to the first side 110A). Furthermore, the one or more semiconductor die 104 may be coupled to the power substrate 134 (e.g., the first conducting layer 136) via a die-attach material 144. In this manner, the power substrate 134 may be on the thermoelectric structure 108, and the one or more semiconductor die 104 may be on the power substrate 134.

It should be understood that the die-attach materials 142, 144 may be similar to the die-attach material 106 coupling the thermoelectric structure 108 to the submount 102. In some examples, the die-attach materials 142, 144 may include the same material as the die-attach material 106. In other examples, the die-attach materials 142, 144 may include a different material than the die-attach material 106. Moreover, in some examples, the die-attach material 144 may include the same material as the die-attach material 142. In other examples, the die-attach material 144 may include a different material than the die-attach material 142. Those having ordinary skill in the art, using the disclosures provided herein, will understand that any suitable die-attach material 106, 142, 144 may be used without deviating from the scope of the present disclosure.

As noted above, the thermoelectric structure 108 may be operable to adjust a temperature difference between the first side 110A of the thermoelectric structure 108 and the second side 110B of the thermoelectric structure 108 based on a bias voltage applied to one of the bias voltage connection structures (e.g., first connection structure 124, second connection structure 126). In this manner, the thermoelectric structure 108 may be operable to pull heat from the one or more semiconductor die 104, through the power substrate 134 and the array 120 of thermoelectric semiconductor structures 114, to the submount 102.

Although depicted in FIGS. 6A-6B as having one or more lateral semiconductor devices, in some examples, the semiconductor die 104 may include one or more vertical semiconductor devices. More particularly, in such examples, the die-attach material 144 may provide for an electrical connection between the semiconductor die 104 and the power substrate 134 such that the semiconductor die 104 is electrically coupled to the power substrate 134.

As another illustrative example, FIGS. 7A-7B depict perspective views of the example semiconductor device package 100 discussed above according to example embodiments of the present disclosure. More particularly, FIG. 7A depicts another perspective view of the example semiconductor device package 100. FIG. 7B depicts a compressed perspective view of the example semiconductor device package 100 depicted in FIG. 7A with a translucent first side 110A/first layer 112A and submount 146 to show the array 120 of thermoelectric semiconductor structures 114 of the thermoelectric structure 108. FIGS. 7A-7B are intended to represent structures for identification and description and is not intended to represent the structures to physical scale.

As noted above, in some examples, the semiconductor device package 100 may include multiple submounts and a plurality of semiconductor die 104. For instance, the submount 102 may be a first submount 102, and the semiconductor device package 100 may also include a second submount 146 on an opposing side of the thermoelectric structure 108 from the first submount 102. As shown, the second submount 146 may be on (e.g., coupled to) the first side 110A of the thermoelectric structure 108, and the plurality of semiconductor die 104 may be on (e.g., coupled to) the second submount 146. A die-attach material 148 may couple the plurality of semiconductor die 104 to the second submount 146. It should be understood that the die-attach material 148 may be similar to the die-attach material 106 coupling the thermoelectric structure 108 to the first submount 102. In some examples, the die-attach material 148 may include the same material as the die-attach material 106. In other examples, the die-attach material 148 may include a different material than the die-attach material 106. Those having ordinary skill in the art, using the disclosures provided herein, will understand that any suitable die-attach material 106, 148 may be used without deviating from the scope of the present disclosure.

As noted above, the thermoelectric structure 108 may be operable to adjust a temperature difference between the first side 110A of the thermoelectric structure 108 and the second side 110B of the thermoelectric structure 108 based on a bias voltage applied to one of the bias voltage connection structures (e.g., first connection structure 124, second connection structure 126). In this manner, the thermoelectric structure 108 may be operable to pull heat from the plurality of semiconductor die 104, through the second submount 146 and the array 120 of thermoelectric semiconductor structures 114, to the first submount 102.

Although depicted in FIGS. 7A-7B as having one or more lateral semiconductor devices, in some examples, the plurality of semiconductor die 104 may include one or more vertical semiconductor devices. More particularly, in such examples, the die-attach material 148 may provide for an electrical connection between the plurality of semiconductor die 104 and the second submount 146 such that each of the plurality of semiconductor die 104 are electrically coupled to the second submount 146.

As another illustrative example, FIGS. 8A-8B depict perspective views of the example semiconductor device package 100 discussed above according to example embodiments of the present disclosure. More particularly, FIG. 8A depicts another perspective view of the example semiconductor device package 100. FIG. 8B depicts a compressed perspective view of the example semiconductor device package 100 depicted in FIG. 8A with a translucent first side 110A/first layer 112A to show the array 120 of thermoelectric semiconductor structures 114 of the thermoelectric structure 108. FIGS. 8A-8B are intended to represent structures for identification and description and is not intended to represent the structures to physical scale.

The example semiconductor device package 100 depicted in FIGS. 8A-8B may be similar to the example semiconductor device package 100 discussed above and depicted in FIGS. 6A-6B. For instance, the semiconductor device package 100 may include one or more semiconductor die 104 (not shown) on the first conducting layer 136 of the power substrate 134. However, in contrast to the example semiconductor device package 100 discussed above and depicted in FIGS. 6A-6B, the one or more semiconductor die 104 may be mounted on the thermoelectric structure 108 in a flip-chip configuration. In other words, as shown, the one or more semiconductor die 104 may be coupled between the first conducting layer 136 of the power substrate 134 and the first side 110A of the thermoelectric structure 108. For instance, in some examples, the one or more semiconductor die 104 may be coupled to the first conducting layer 136 of the power substrate 134 via a die-attach material (not shown), such as any of the die-attach materials described herein. In such examples, one or more connection structures (not shown) of the one or more semiconductor die 104, such as the connection structures 130 (FIGS. 5A-5B) discussed above, may be electrically coupled (e.g., through the die-attach material) to the first conducting layer 136.

As another illustrative example, FIGS. 9A-9B depict perspective views of the example semiconductor device package 100 discussed above according to example embodiments of the present disclosure. More particularly, FIG. 9A depicts another perspective view of the example semiconductor device package 100. FIG. 9B depicts a compressed perspective view of the example semiconductor device package 100 depicted in FIG. 9A with a translucent first side 110A/first layer 112A and a translucent second side 152B/second layer 154B to show the array 120 of thermoelectric semiconductor structures 114 of the thermoelectric structure 108 and the thermoelectric structure 150, respectively. FIGS. 9A-9B are intended to represent structures for identification and description and is not intended to represent the structures to physical scale.

As noted above, in some examples, the semiconductor device package 100 may include multiple thermoelectric structures and a plurality of semiconductor die 104. For instance, the thermoelectric structure 108 may be a first thermoelectric structure 108, and the semiconductor device package 100 may also include a second thermoelectric structure 150. It should be understood that the second thermoelectric structure 150 may include the same components and may operate in a similar manner as discussed above with reference to the thermoelectric structure 108. For instance, the second thermoelectric structure 150 may be operable to adjust a temperature difference between a first side 152A of the second thermoelectric structure 150 and a second side 152B of the second thermoelectric structure 150 based on a bias voltage applied to the second thermoelectric structure 152. The second thermoelectric structure 150 may include a first layer 154A and a second layer 154B that respectively define the first side 152A and the second side 152B. Thus, in some examples (e.g., FIGS. 9A-9B), the second thermoelectric structure 150 may have an opposite orientation from the first thermoelectric structure 108.

As shown, the plurality of semiconductor die 104 may be coupled to the first side 110A of the first thermoelectric structure 108 and, similarly, to the first side 152A of the second thermoelectric structure 150. In this manner, the second thermoelectric semiconductor structure 150 may be on a side of the plurality of semiconductor die 104 that is opposite from the first thermoelectric structure 108.

As noted above, the first thermoelectric structure 108 may be operable to adjust a temperature difference between the first side 110A of the first thermoelectric structure 108 and the second side 110B of the first thermoelectric structure 108 based on a bias voltage applied to one of the bias voltage connection structures (e.g., first connection structure 124, second connection structure 126). In this manner, the first thermoelectric structure 108 may be operable to pull heat from the one or more semiconductor die 104, through the array 120 of thermoelectric semiconductor structures 114, to the submount 102.

Moreover, the second thermoelectric structure 150 may include a first connection structure 156 and a second connection structure 158 and a plurality of thermoelectric semiconductor structures 160 arranged in series (e.g., in an array) therebetween. Thus, like the first thermoelectric structure 108, the second thermoelectric structure 150 may be operable to adjust a temperature difference between the first side 152A of the second thermoelectric structure 150 and the second side 152B of the second thermoelectric structure 150 based on a bias voltage applied to one of the bias voltage connection structures (e.g., first connection structure 156, second connection structure 158). In this manner, the second thermoelectric structure 150 may be operable to pull heat from the one or more semiconductor die 104 through the array of thermoelectric semiconductor structures 160.

Although depicted in FIGS. 9A-9B as having one or more lateral semiconductor devices, in some examples, the plurality of semiconductor die 104 may include one or more vertical semiconductor devices. More particularly, in some examples, the first thermoelectric structure 108 may include a thermally conductive heat sink (e.g., heat sink 132 (FIGS. 5A-5B). In such examples, a die-attach material 162 (FIG. 9A) may provide for an electrical connection between the plurality of semiconductor die 104 and the thermally conductive heat sink such that each of the plurality of semiconductor die 104 are electrically coupled to the thermally conductive heat sink.

FIGS. 5A-9B depict example semiconductor device packages and thermoelectric structures for purposes of illustration and discussion. Those of ordinary skill in the art, using the disclosures provided herein, will understand that different semiconductor device package configurations and/or thermoelectric structure configurations may be used without deviating from the scope of the present disclosure.

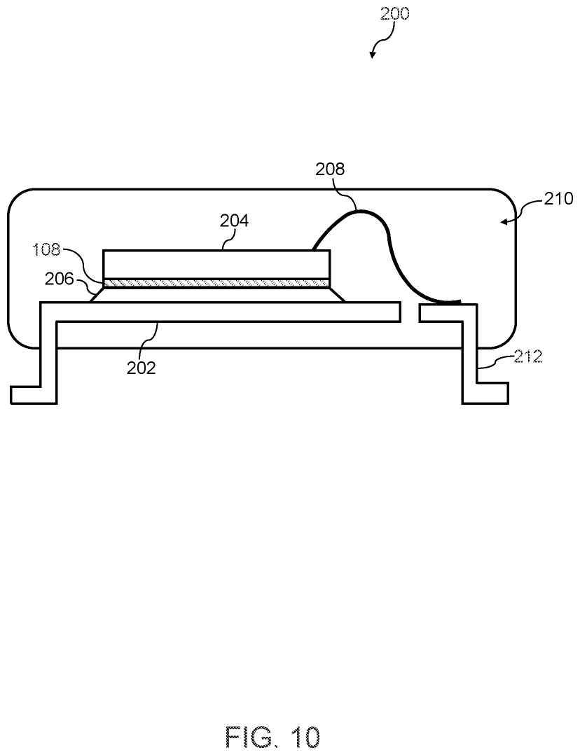

FIG. 10 depicts an example semiconductor package 200 of a semiconductor device according to example embodiments of the present disclosure. The semiconductor package 200 may be, for instance, a discrete semiconductor device package. FIG. 10 is provided for purposes of illustration and discussion. Those having ordinary skill in the art, using the disclosures provided herein, will understand that aspects of the present disclosure may be used in a variety of devices and/or applications without deviating from the scope of the present disclosure. Furthermore, FIG. 10 is intended to represent structures for identification and description and is not intended to represent the structures to physical scale. It should be understood that the semiconductor package 200 may include one or more thermoelectric structures, such as the thermoelectric structures 108, 150 described above with reference to FIGS. 2-9B. It should be further understood that the semiconductor package 200 may include any of the various configurations described herein with reference to FIGS. 2-9B.

Referring to FIG. 10, as shown, the semiconductor package 200 may include a conductive submount 202 (e.g., a patterned conductive substrate, lead frame, clip structure or other power substrate) on which the thermoelectric structure 108, which is coupled to a semiconductor die 204 containing one or more power devices (e.g., transistors, diodes, etc.), is attached using a die-attach material 206. The die-attach material 206 may provide a thermal, mechanical, and electrical connection between the thermoelectric structure 108 and the conductive submount 202. It should be understood that, although depicted as having the thermoelectric structure 108, the semiconductor package 200 may include any of the thermoelectric structures discussed herein.

In some examples, the semiconductor die 204 may also be connected to the conductive submount 202 using wire bonds 208. An encapsulating material 210 (e.g., epoxy mold compound (EMC)) may fill the space around the semiconductor die 204 and the submount 202, thereby defining an encapsulating portion of the semiconductor package 200 and forming a housing. The semiconductor package 200 may further include at least one connection structure extending from the housing, such as one or more electrical leads 212 that extend outward from the housing (e.g., outward from the encapsulating material 210). Although depicted as the one or more electrical leads 212, the at least one connection structure may be any suitable connection structure (e.g., pins, terminals, contacts, interconnects, bonding pads, etc.) without deviating from the scope of the present disclosure. Furthermore, the at least one connection structure extending from the housing may be coupled to one or more thermoelectric structures (FIGS. 2-9B).

The semiconductor die 204 may include one or more metallization structures, such as bonding pads (e.g., connection structures 130 (FIGS. 5A-5B), etc.). The bonding pads may be coupled to the one or more electrical leads 212 using the wire bonds 208. The wire bonds 208 may be aluminum and/or copper. The wire bonds 208 may have a thickness of about 15 mil to about 20 mil (e.g., about 381 μm to about 508 μm). As noted above, the bonding pads may have a thickness, for instance, of about 4 μm or less. The encapsulating material 210 may encapsulate the semiconductor die 204, including its thermoelectric structures, metallization structures, wire bonds 208, submount 202, and other portions of the semiconductor package 200. In some examples, the encapsulating material 210 (e.g., encapsulating portion) may directly contact the metallization structures and the thermoelectric structures of the semiconductor package 200.

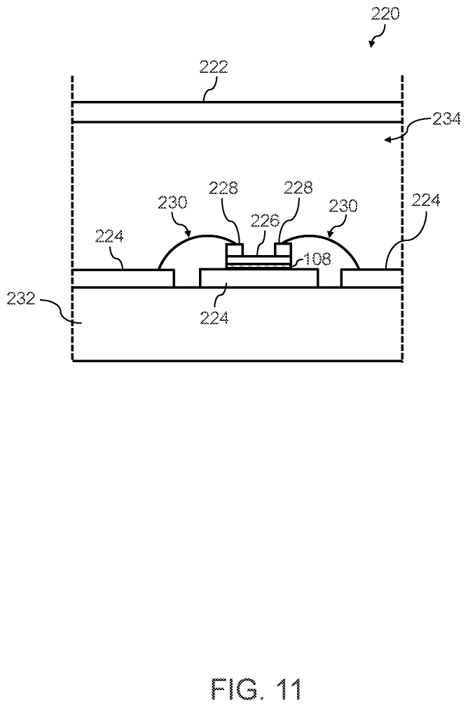

FIG. 11 depicts a cross-sectional view of an example semiconductor package of a semiconductor device 220 according to example embodiments of the present disclosure. The semiconductor device 220 of FIG. 11 is a portion of a power module. FIG. 11 is intended to represent structures for identification and description and is not intended to represent the structures to physical scale. It should be understood that the example power module of FIG. 11 may include one or more thermoelectric structures, such as the thermoelectric structures 108, 150 described above with reference to FIGS. 2-9B. It should be further understood that the example power module of FIG. 11 may include any of the various configurations described herein with reference to FIGS. 2-9B.

The semiconductor device 220 may include a housing 222. The semiconductor device 220 may include a conductive submount 224 (e.g., a patterned conductive submount) on which the thermoelectric structure 108, which is coupled to a semiconductor die 226, is mounted (e.g., using a die-attach material). For instance, the thermoelectric structure 108 may be mounted on submount 224 using a die-attach material that includes a sintered material, such as sintered silver and/or sintered copper. It should be understood that, although depicted as having the thermoelectric structure 108, the semiconductor device 220 may include any of the thermoelectric structures discussed herein.

The semiconductor die 226 may include one or more connection structures, such as bonding pads 228. In some embodiments, the semiconductor die 226 may be connected to the conductive submount 224 using wire bonds 230. The conductive submount 224 may be mounted on a base layer 232 (e.g., an insulating layer). An inert gel 234 may fill the space between the semiconductor die 226 and the housing 222.

FIGS. 10-11 depict example semiconductor packages for purposes of illustration and discussion. Those of ordinary skill in the art, using the disclosures provided herein, will understand that different semiconductor package configurations may be used without deviating from the scope of the present disclosure.

Example aspects of the present disclosure are set forth below. Any of the below features or examples may be used in combination with any of the embodiments or features provided in the present disclosure.

One example aspect of the present disclosure is directed to a semiconductor device package. The semiconductor device package includes a submount, a thermoelectric structure on the submount, and one or more semiconductor die on the thermoelectric structure. The thermoelectric structure is operable to adjust a temperature difference between a first side of the thermoelectric structure and a second side of the thermoelectric structure based on a bias voltage applied to the thermoelectric structure.

In some examples, the thermoelectric structure includes a first layer defining the first side of the thermoelectric structure, a second layer defining the second side of the thermoelectric structure, and a plurality of thermoelectric semiconductor structures between the first layer and the second layer.

In some examples, the thermoelectric structure includes a thermoelectric film.

In some examples, the first layer and the second layer include one of or more of aluminum oxide or aluminum nitride.

In some examples, each of the first layer and the second layer have a thickness in a range of about 0.3 microns to about 5 microns.

In some examples, the plurality of thermoelectric semiconductor structures are arranged in an array between the first layer and the second layer.

In some examples, the semiconductor device package further includes a plurality of interconnects coupling adjacent thermoelectric semiconductor structures in the array, the plurality of interconnects including one or more first interconnects contacting the first layer and one or more second interconnects contacting the second layer.

In some examples, each thermoelectric semiconductor structure includes a first side and an opposing second side, each of the first interconnects contacting a respective first side and each of the second interconnects contacting a respective second side.

In some examples, the plurality of interconnects are copper traces.

In some examples, each interconnect of the plurality of interconnects has a thickness in a range of about 0.2 microns to about 10 microns.

In some examples, each of the plurality of thermoelectric semiconductor structures are separated from adjacent thermoelectric semiconductor structures by a distance in a range of about 1 micron to about 100 microns.

In some examples, each of the plurality of thermoelectric semiconductor structures has a thickness in a range of about 0.1 microns to about 20 microns.

In some examples, each of the plurality of thermoelectric semiconductor structures has a length in a range of about 1 micron to about 1000 microns.

In some examples, each of the plurality of thermoelectric semiconductor structures has a width in a range of about 1 micron to about 1000 microns.

In some examples, the thermoelectric structure includes a plurality of p-type thermoelectric semiconductor structures and a plurality of n-type thermoelectric semiconductor structures.

In some examples, the plurality of p-type thermoelectric semiconductor structures and the plurality of n-type thermoelectric semiconductor structures are arranged in an array, the plurality of p-type thermoelectric semiconductor structures being alternately arranged with the plurality of n-type thermoelectric semiconductor structures in the array.

In some examples, the plurality of p-type thermoelectric semiconductor structures and the plurality of n-type thermoelectric semiconductor structures include a bismuth alloy.

In some examples, each of the plurality of p-type thermoelectric semiconductor structures include bismuth telluride doped with antimony, and each of the plurality of n-type thermoelectric semiconductor structures include bismuth telluride doped with selenium.

In some examples, the plurality of p-type thermoelectric semiconductor structures and the plurality of n-type thermoelectric semiconductor structures include a conductive polymer.

In some examples, the conductive polymer is one of poly polystyrene sulfonate (PEDOT:PSS), polyaniline (PANI), polythiophene (PTH), or polyphenylene vinylene (PPV).

In some examples, each of the plurality of p-type thermoelectric semiconductor structures include a PEDOT-carbon nanotube (CNT) composite, and each of the plurality of n-type thermoelectric semiconductor structures include a polyethylenimine (PEI) doped PEDOT-carbon nanotube (CNT) composite.

In some examples, the thermoelectric structure further includes a first connection structure coupled to one of the plurality of n-type thermoelectric semiconductor structures and a second connection structure coupled to one of the plurality of p-type thermoelectric semiconductor structures.

In some examples, the first connection structure is a first bias voltage connection structure and the second connection structure is a second bias voltage connection structure.

In some examples, the first connection structure and the second connection structure are each one of a pin, a lead, a terminal, a contact, an interconnect, or a bonding pad.

In some examples, the semiconductor device package further includes a power substrate between the thermoelectric structure and the one or more semiconductor die, and the one or more semiconductor die are on the power substrate.

In some examples, the power substrate includes a first conducting layer, a second conducting layer, and an insulating layer between the first conducting layer and the second conducting layer.

In some examples, the submount is a first submount, and the one or more semiconductor die include a plurality of semiconductor die. The semiconductor device package further includes a second submount on the first side of the thermoelectric structure, and the plurality of semiconductor die are on the second submount.

In some examples, the one or more semiconductor die is mounted on the thermoelectric structure in a flip-chip configuration.

In some examples, the thermoelectric structure is a first thermoelectric structure, and the semiconductor device package further includes a second thermoelectric structure on a side of the one or more semiconductor die opposite from the first thermoelectric structure.

In some examples, the semiconductor device package further includes a heat sink coupled to the thermoelectric structure.

In some examples, the heat sink includes a thermally conductive material.

In some examples, the semiconductor device package further includes a housing.

In some examples, the housing includes an epoxy mold compound (EMC).

In some examples, the semiconductor device package is a discrete semiconductor package.

In some examples, the semiconductor device package is a power module.

In some examples, the semiconductor device package further includes a die-attach material coupling the one or more semiconductor die to the first side of the thermoelectric structure, and the die-attach material is a sintered material.

In some examples, the one or more semiconductor die include a wide bandgap semiconductor device.

In some examples, the wide bandgap semiconductor device includes a silicon carbide-based metal-oxide-semiconductor field-effect transistor (MOSFET), a silicon carbide-based Schottky diode, or a Group-III nitride-based high electron mobility transistor (HEMT) device.

Another example aspect of the present disclosure is directed to a semiconductor device package. The semiconductor device package includes a thermoelectric structure having an array of thermoelectric semiconductor structures. The semiconductor device package includes a semiconductor die on the thermoelectric structure.

In some examples, the semiconductor die includes a wide bandgap semiconductor device.

In some examples, the thermoelectric structure includes a first layer defining a first side of the thermoelectric structure and a second layer defining a second side of the thermoelectric structure, and the array of thermoelectric semiconductor structures is between the first layer and the second layer.

In some examples, the thermoelectric structure includes a thermoelectric film.

In some examples, the first layer and the second layer include one of aluminum oxide or aluminum nitride.

In some examples, each of the first layer and the second layer have a thickness in a range of about 0.3 microns to about 5 microns.

In some examples, the semiconductor device package further includes a plurality of interconnects coupling adjacent thermoelectric semiconductor structures in the array, the plurality of interconnects including one or more first interconnects contacting the first layer and one or more second interconnects contacting the second layer.

In some examples, each thermoelectric semiconductor structure includes a first side and an opposing second side, each of the first interconnects contacting a respective first side and each of the second interconnects contacting a respective second side.

In some examples, the plurality of interconnects are copper traces.

In some examples, each interconnect of the plurality of interconnects has a thickness in a range of about 0.2 microns to about 10 microns.

In some examples, each semiconductor structure in the array has a thickness in a range of about 0.1 microns to about 20 microns, a length in a range of about 1 micron to about 1000 microns, a width in a range of about 1 micron to about 1000 microns, and is separated from adjacent thermoelectric semiconductor structures in the array by a distance in a range of about 1 micron to about 100 microns.

In some examples, the array includes a plurality of p-type thermoelectric semiconductor structures and a plurality of n-type thermoelectric semiconductor structures, the plurality of p-type thermoelectric semiconductor structures being alternately arranged with the plurality of n-type thermoelectric semiconductor structures in the array.

In some examples, the plurality of p-type thermoelectric semiconductor structures and the plurality of n-type thermoelectric semiconductor structures include a bismuth alloy.

In some examples, each of the plurality of p-type thermoelectric semiconductor structures includes bismuth telluride doped with antimony, and each of the plurality of n-type thermoelectric semiconductor structures includes bismuth telluride doped with selenium.

In some examples, plurality of p-type thermoelectric semiconductor structures and the plurality of n-type thermoelectric semiconductor structures include a conductive polymer.

In some examples, the conductive polymer is one of poly polystyrene sulfonate (PEDOT:PSS), polyaniline (PANI), polythiophene (PTH), or polyphenylene vinylene (PPV).

In some examples, each of the plurality of p-type thermoelectric semiconductor structures includes a PEDOT-carbon nanotube (CNT) composite, and each of the plurality of n-type thermoelectric semiconductor structures includes a polyethylenimine (PEI) doped PEDOT-carbon nanotube (CNT) composite.

In some examples, the thermoelectric structure further includes a first bias voltage connection structure coupled to a first end of the array and a second bias voltage connection structure coupled to a second end of the array, and the plurality of p-type thermoelectric semiconductor structures and the plurality of n-type thermoelectric semiconductor structures are alternately arranged in series between the first end of the array and the second end of the array.

In some examples, the first bias voltage connection structure and the second bias voltage connection structure are each one of a pin, a lead, a terminal, a contact, an interconnect, or a bonding pad.

Another example aspect of the present disclosure is directed to a semiconductor device package. The semiconductor device package includes a housing, a submount, a thermoelectric structure, at least one connection structure extending from the housing, and at least one semiconductor die on the thermoelectric structure. The at least one connection structure is coupled to the thermoelectric structure.

In some examples, the thermoelectric structure is operable to adjust a temperature difference between a first side of the thermoelectric structure and a second side of the thermoelectric structure based on a bias voltage applied to the thermoelectric structure.

In some examples, the at least one connection structure is one of a pin, a lead, a terminal, a contact, an interconnect, or a bonding pad.

In some examples, the semiconductor device package further includes at least one source connection structure, at least one gate connection structure, and at least one drain connection structure.

In some examples, each of the at least one source connection structure, the at least one gate connection structure, and the at least one drain connection structure are each one of a pin, a lead, a terminal, a contact, an interconnect, or a bonding pad.

In some examples, the semiconductor device package further includes a power substrate between the thermoelectric structure and the at least one semiconductor die, and the at least one semiconductor die is on the power substrate.

In some examples, the power substrate includes a first conducting layer, a second conducting layer, and an insulating layer between the first conducting layer and the second conducting layer.

In some examples, the submount is a first submount, and the semiconductor device package further includes a second submount on an opposing side of the thermoelectric structure from the first submount. The at least one semiconductor die is on the second submount.

In some examples, the at least one semiconductor die is mounted on the thermoelectric structure in a flip-chip configuration.

In some examples, the thermoelectric structure is a first thermoelectric structure, and the semiconductor device package further includes a second thermoelectric structure on a side of the at least one semiconductor die opposite from the first thermoelectric structure.

In some examples, the semiconductor device package further includes a heat sink coupled to the thermoelectric structure.

In some examples, the heat sink includes a thermally conductive material.

In some examples, the housing includes an epoxy mold compound (EMC).

In some examples, the submount includes a lead frame.

In some examples, the submount includes copper.

In some examples, the at least one semiconductor die includes at least one wide bandgap semiconductor device.

In some examples, the at least one wide bandgap semiconductor device includes one of a silicon carbide-based metal-oxide-semiconductor field-effect transistor (MOSFET), a silicon carbide-based Schottky diode, or a Group-III nitride-based high electron mobility transistor (HEMT) device.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device package, comprising:
a submount;
a thermoelectric structure on the submount, the thermoelectric structure operable to adjust a temperature difference between a first side of the thermoelectric structure and a second side of the thermoelectric structure based on a bias voltage applied to the thermoelectric structure; and
one or more semiconductor die on the thermoelectric structure.

2-14. (canceled)

15. The semiconductor device package of claim 1, wherein the thermoelectric structure comprises a plurality of p-type thermoelectric semiconductor structures and a plurality of n-type thermoelectric semiconductor structures.

16. (canceled)

17. The semiconductor device package of claim 15, wherein the plurality of p-type thermoelectric semiconductor structures and the plurality of n-type thermoelectric semiconductor structures comprise a bismuth alloy.

18. (canceled)

19. The semiconductor device package of claim 15, wherein the plurality of p-type thermoelectric semiconductor structures and the plurality of n-type thermoelectric semiconductor structures comprise a conductive polymer, the conductive polymer being one of poly polystyrene sulfonate (PEDOT:PSS), polyaniline (PANI), polythiophene (PTH), or polyphenylene vinylene (PPV).

20-24. (canceled)

25. The semiconductor device package of claim 1, further comprising a power substrate between the thermoelectric structure and the one or more semiconductor die, wherein:
the power substrate comprises a first conducting layer, a second conducting layer, and an insulating layer between the first conducting layer and the second conducting layer, and
the one or more semiconductor die are on the power substrate.

26. (canceled)

27. The semiconductor device package of claim 1, wherein the submount is a first submount, wherein the one or more semiconductor die comprises a plurality of semiconductor die, the semiconductor device package further comprising:
a second submount on the first side of the thermoelectric structure,
wherein the plurality of semiconductor die are on the second submount.

28. (canceled)

29. The semiconductor device package of claim 1, wherein the thermoelectric structure is a first thermoelectric structure, the semiconductor device package further comprising a second thermoelectric structure on a side of the one or more semiconductor die opposite from the first thermoelectric structure.

30-33. (canceled)

34. The semiconductor device package of claim 1, wherein the semiconductor device package is one of a discrete semiconductor package or a power module.

35-38. (canceled)

39. A semiconductor device package, comprising:
a thermoelectric structure comprising an array of thermoelectric semiconductor structures; and
a semiconductor die on the thermoelectric structure.

40. (canceled)

41. The semiconductor device package of claim 39, wherein the thermoelectric structure comprises a first layer defining a first side of the thermoelectric structure and a second layer defining a second side of the thermoelectric structure, and wherein the array of thermoelectric semiconductor structures is between the first layer and the second layer.

42. The semiconductor device package of claim 41, wherein the thermoelectric structure comprises a thermoelectric film, each of the first layer and the second layer having a thickness in a range of about 0.3 microns to about 5 microns.

43-44. (canceled)

45. The semiconductor device package of claim 41, further comprising a plurality of interconnects coupling adjacent thermoelectric semiconductor structures in the array, the plurality of interconnects comprising one or more first interconnects contacting the first layer and one or more second interconnects contacting the second layer,
wherein each thermoelectric semiconductor structure comprises a first side and an opposing second side, each of the first interconnects contacting a respective first side and each of the second interconnects contacting a respective second side.

46-48. (canceled)

49. The semiconductor device package of claim 39, wherein each semiconductor structure in the array has a thickness in a range of about 0.1 microns to about 20 microns, a length in a range of about 1 micron to about 1000 microns, a width in a range of about 1 micron to about 1000 microns, and is separated from adjacent thermoelectric semiconductor structures in the array by a distance in a range of about 1 micron to about 100 microns.

50. The semiconductor device package of claim 39, wherein the thermoelectric structure further comprises a first bias voltage connection structure coupled to a first end of the array and a second bias voltage connection structure coupled to a second end of the array, and
wherein the array comprises a plurality of p-type thermoelectric semiconductor structures and a plurality of n-type thermoelectric semiconductor structures, the plurality of p-type thermoelectric semiconductor structures being alternately arranged in series with the plurality of n-type thermoelectric semiconductor structures between the first end of the array and the second end the array.

51. (canceled)

52. The semiconductor device package of claim 50, wherein each of the plurality of p-type thermoelectric semiconductor structures comprises bismuth telluride doped with antimony, and each of the plurality of n-type thermoelectric semiconductor structures comprises bismuth telluride doped with selenium.

53-54. (canceled)

55. The semiconductor device package of claim 50, wherein each of the plurality of p-type thermoelectric semiconductor structures comprises a PEDOT-carbon nanotube (CNT) composite, and each of the plurality of n-type thermoelectric semiconductor structures comprises a polyethylenimine (PEI) doped PEDOT-carbon nanotube (CNT) composite.

56-57. (canceled)

58. A semiconductor device package, comprising:
a housing;
a submount;
a thermoelectric structure;
at least one connection structure extending from the housing, the at least one connection structure coupled to the thermoelectric structure; and
at least one semiconductor die on the thermoelectric structure.

59. (canceled)

60. The semiconductor device package of claim 58, wherein the at least one connection structure is one of a pin, a lead, a terminal, a contact, an interconnect, or a bonding pad.

61-67. (canceled)

68. The semiconductor device package of claim 58, further comprising a heat sink coupled to the thermoelectric structure, wherein the heat sink comprises a thermally conductive material.

69-72. (canceled)

73. The semiconductor device package of claim 58, wherein the at least one semiconductor die comprises at least one wide bandgap semiconductor device, the at least one wide bandgap semiconductor device comprising one of a silicon carbide-based metal-oxide-semiconductor field-effect transistor (MOSFET), a silicon carbide-based Schottky diode, or a Group-III nitride-based high electron mobility transistor (HEMT) device.

74. (canceled)
